(19) United States
(12) Patent Application Publication
(10) Pub. No.: US 2026/0206199 A1
(43) Pub. Date: Jul. 16, 2026

(54) BEOL METAL LINE FORMATION PROCESSING

(71) Applicant: Taiwan Semiconductor Manufacturing Co., Ltd., Hsinchu (TW)

(72) Inventors: Yu-Chin HUANG, Hsinchu (TW); Yu-Cheng CHIEN, Hsinchu (TW); Pin-Zhen CHEN, Hsinchu (TW); Chih-Hao CHEN, Hsinchu (TW); Meng-Wei CHEN, Hsinchu (TW)

(73) Assignee: Taiwan Semiconductor Manufacturing Co., Ltd., Hsinchu (TW)

(21) Appl. No.: 19/203,014

(22) Filed: May 8, 2025

Related U.S. Application Data
(60) Provisional application No. 63/745,643, filed on Jan. 15, 2025.

(51) Int. Cl. H10B 10/00; H01L 21/027; H01L 21/033; H01L 21/768; H01L 23/528

(52) U.S. Cl. CPC H10B 10/12; H10P 76/20; H10P 76/405; H10W 20/056; H10W 20/062; H10W 20/43; H10W 20/435

(57) ABSTRACT

A process forms alternating first and second metal lines in an interlevel dielectric layer. A first photolithography and etching process forms trenches in a patterning layer. A plurality of dielectric spacers are formed on sidewalls of the trenches. A second photolithography and etching process forms a pattern of the first metal lines in a hard mask layer between the interlevel dielectric layer and the patterning layer based on the dielectric spacers. A third photolithography and etching process forms a pattern of a second metal lines in the hard mask layer based on the dielectric spacers. The patterns of the first and second metal lines are then transferred by an etching process to the interlevel dielectric layer as trenches in the interlevel dielectric layer. The first and second groups of the metal lines are then formed simultaneously by depositing a metal material in the trenches in the interlevel dielectric layer.

### BACKGROUND

The semiconductor integrated circuit industry has experienced exponential growth. Technological advances in integrated circuit materials and design have produced generations of integrated circuits in which each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

One aspect of integrated circuit processing is the formation of metal lines in dielectric layers. In the scaling down process, it is desirable that metal lines shrink in width so that the density of metal lines increases. However, the scaling down process presents difficulties when it comes to patterning and forming the metal lines with ever shrinking widths and pitches. These difficulties can lead to malformation of metal lines. This malformation can include undesired widening of metal lines, resulting in increased capacitances or even short circuits.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventor's approach to the particular problem, which, in and of itself, may also be inventive.

### BRIEF DESCRIPTION OF THE DRAWINGS

FIGS. 1-13C are cross-sectional views and top views of an integrated circuit at various stages of processing, in accordance with some embodiments.

FIG. 14 is a cross-sectional view of an integrated circuit, in accordance with some embodiments.

FIG. 15A is a layout of an integrated circuit, in accordance with some embodiments.

FIG. 15B is a top view of an integrated circuit in which the layout of FIG. 15A has been implemented, in accordance with some embodiments.

FIG. 16 is a cross-sectional view of an integrated circuit, in accordance with some embodiments.

FIG. 17 is a cross-sectional view of an integrated circuit, in accordance with some embodiments.

FIG. 18 is a cross-sectional view of an integrated circuit, in accordance with some embodiments.

FIG. 19 is a flow diagram of a method for forming an integrated circuit, in accordance with some embodiments.

FIG. 20 is a flow diagram of a method for forming an integrated circuit, in accordance with some embodiments.

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “some embodiments” or “an embodiment” means that a particular feature, structure or characteristic described in connection with the embodiment is included in at least some embodiments. Thus, the appearances of the phrases “in some embodiments” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

As used in this specification, “light” generally refers to electromagnetic radiation of any wavelength, except where a particular band or wavelength is specified. Accordingly, unless specified otherwise, “light” refers to x-ray radiation, EUV radiation, ultraviolet (UV) radiation, visible radiation, infrared radiation, or other bands, wavelengths, or categories of electromagnetic radiation. Furthermore, as used herein, “optical systems” can include any system that receives/generates and utilizes electromagnetic radiation.

Embodiments of the present disclosure provide a method for forming metal lines in an interlevel dielectric layer of an integrated circuit. The process forms a set of metal lines as a first group of metal lines and a second group of metal lines laterally interleaved with the first group of metal lines. The process forms a patterning layer over the interlevel dielectric layer. A first photolithography and etching process forms tracks in the patterning layer. A plurality of dielectric spacers are formed on sidewalls of the tracks, with the bottoms of the tracks exposed. A second photolithography and etching process forms a pattern of the first group of metal lines in the patterning layer, based on the dielectric spacers. A third photolithography and etching process forms a pattern of the second group of metal lines in the patterning layer, based on the dielectric spacers. The patterns of the first and second groups of metal lines are then transferred by an etching process to the interlevel dielectric layer as trenches in the interlevel dielectric layer. The first and second groups of the metal lines are then formed simultaneously by depositing a metal material in the trenches.

Embodiments of the present disclosure provide several benefits. First of all, there is no separate photolithography and etching process to form breaks in the metal lines. Secondly, in the patterning layer the trenches or windows for both the first group of metal lines and the second group of metal lines are confined by the dielectric spacers. This enables both groups of metal lines to have multiple end-to-end dimensions or small dimensions (e.g., very small end-to-end distances). There is also a tremendous reduction in excess line length and redundant metal. The lines do not have laterally enlarged characteristics at non-confined locations. This further results in better functioning integrated circuits and fewer scrapped wafers.

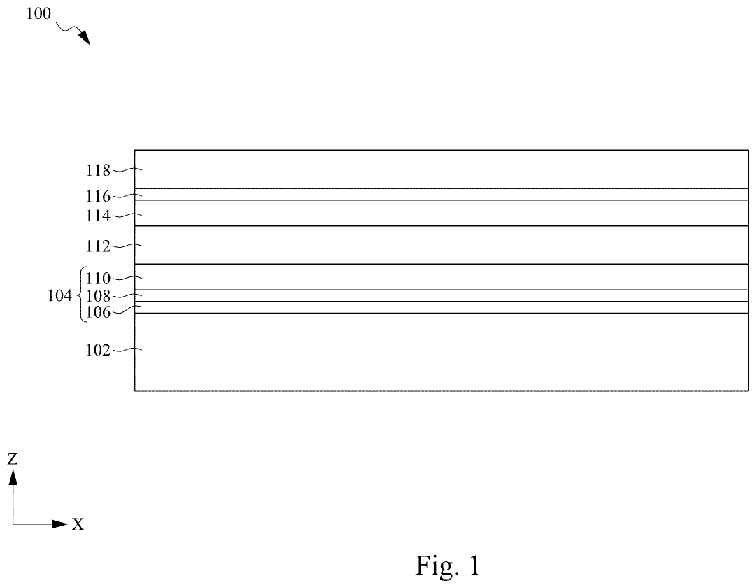

FIGS. 1-13C are cross-sectional and top views of an integrated circuit 100 at various stages of processing, in accordance with some embodiments. FIGS. 1-13C illustrate formation of metal lines in interlevel dielectric layer. The process illustrated in relation to FIGS. 1-13C efficiently and effectively forms the metal lines with improved characteristics with respect to other possible solutions. The process corresponds to a back end of line (BEOL) process.

FIG. 1 is a cross-sectional view of the integrated circuit 100, in accordance with some embodiments. FIG. 1 illustrates an interlevel dielectric layer 102. In some embodiments, the interlevel dielectric layer includes a low-K dielectric material. In some embodiments, the interlevel dielectric layer 102 includes silicon oxide (e.g., SiO2). The interlevel dielectric layer 102 can include SiON, SiN, SiC, SiOC, SiOCN, SiON, or other suitable dielectric materials. The interlevel dielectric layer 102 can be deposited by chemical vapor deposition (CVD), atomic layer deposition (ALD), or physical vapor deposition (PVD or other suitable deposition processes. The interlevel dielectric layer 120 has a thickness between 50 nm and 500 nm, though other thicknesses can be utilized without departing from the scope of the present disclosure.

Although the interlevel dielectric layer 102 is shown as a single dielectric layer, in some embodiments the interlevel dielectric layer 102 includes multiple dielectric layers stacked on top of each other.

In some embodiments, the interlevel dielectric layer 102 is formed above an active circuit region (not shown). The active circuit region includes a plurality of transistors. The transistors include PMOS transistors and NMOS transistors. In some embodiments, the transistors are core logic circuits. In some embodiments, the transistors makeup a portion of an SRAM array of the integrated circuit 100.

In some embodiments, the active circuit region includes a semiconductor substrate. The channel regions and the source/drain regions of the transistors are formed in conjunction with the semiconductor substrate. The gate dielectric layers and gate metals of the transistors are formed adjacent to the channel regions. The gate contacts, corresponding to conductive vias with conductive plugs, extend downward to contact the gate regions. Source/drain contacts, corresponding to conductive vias or conductive plugs extend downward to contact the source/drain regions. Various dielectric layers including gate spacers are formed over the transistor structures.

The interlevel dielectric layer 102 is formed over the various structures of the active circuit region. Though not shown in FIG. 1, conductive vias may be formed in a lower portion of the interlevel dielectric layer 102. The metal lines that will subsequently be formed in the interlevel dielectric layer 102 may contact the conductive vias at selected locations.

In some embodiments, the integrated circuit 100 includes a hard mask layer 104 over the interlevel dielectric layer 102. As will be set forth in more detail below, the hard mask layer 104 corresponds to a layer that will eventually be patterned with a pattern corresponding to the layout of the metal lines that will be formed in the interlevel dielectric layer 102. After the hard mask layer 104 is patterned, trenches may be formed in the interlevel dielectric layer 102, in accordance with the patterning the hard mask layer 104. A conductive material may then be deposited in the trenches in the interlevel dielectric layer 102, thereby forming the metal lines in the trenches.

In some embodiments, the hard mask layer 104 includes a plurality of hard mask sublayers. In FIG. 1, the hard mask layer 104 includes a first hard mask sublayer 106 on the interlevel dielectric layer 102. The hard mask layer 104 includes a second hard mask sublayer 108 on the first hard mask sublayer 106. The hard mask layer 104 includes a third hard mask sublayer 110 on the second hard mask sublayer 108.

In some embodiments, the first hard mask sublayer 106 includes tetraethyl orthosilicate (TEOS). The first hard mask sublayer 106 can be deposited by CVD, ALD, or PVD. Other deposition processes and materials can be used for the first hard mask sublayer 106 without departing from the scope of the present disclosure. The first hard mask sublayer 106 has a thickness between 20 nm and 28 nm, though other thicknesses can be utilized without departing from the scope of the present disclosure.

In some embodiments, the second hard mask sublayer 108 includes carbon that is doped with tungsten (tungsten doped carbon). The second hard mask sublayer 108 can be deposited by CVD, ALD, or PVD. Other deposition processes and materials can be used for the second hard mask sublayer 108 without departing from the scope of the present disclosure. The second hard mask sublayer 108 has a thickness between 10 nm and 15 nm, though other thicknesses can be utilized without departing from the scope of the present disclosure.

In some embodiments, the third hard mask sublayer 110 includes tetraethyl orthosilicate (TEOS). The third hard mask sublayer 110 can be deposited by CVD, ALD, or PVD. Other deposition processes and materials can be used for the third hard mask sublayer 110 without departing from the scope of the present disclosure. The third hard mask sublayer 110 has a thickness between 7 nm and 12 nm, though other thicknesses can be utilized without departing from the scope of the present disclosure.

In some embodiments, the integrated circuit 100 includes a patterning layer 112 on the hard mask layer 104. In the example FIG. 1, the patterning layer 112 is positioned on the third hard mask sublayer 110. As will be set forth in more detail below, the patterning layer 112 acts as a layer that assists in imparting the patterns of the first and second groups of metal lines to the hard mask layer 104. As will be set forth in more detail below, tracks or trenches will be formed in the patterning layer 112. Spacers will then be formed on the sidewalls of the tracks. The combination of the spacers and the patterning layer 112 will help to impart the pattern of the first and second groups of metal lines to the hard mask layer 104.

In some embodiments, the patterning layer 112 includes amorphous silicon, which has good etch selectivity with respect to the dielectric layer 106 spacers, enabling strong self-alignment., In some embodiments, the patterning layer 112 is deposited by PVD, ALD, or CVD. In some embodiments, the patterning layer 112 has a thickness between 35 nm and 50 nm. Other materials, thicknesses, and deposition processes can be utilized for the patterning layer 112 without departing the scope of the present disclosure.

The integrated circuit 100 includes a dielectric layer 114 on the patterning layer 112, in accordance with some embodiments. In some embodiments, the dielectric layer 114 includes amorphous carbon. In some embodiments, the dielectric layer is deposited by CVD, ALD, or PVD. In some embodiments, the dielectric layer 114 has a thickness between 10 nm and 50 nm. Other materials, deposition processes, and thicknesses can be utilized for the dielectric layer 114 without departing from the scope of the present disclosure.

The integrated circuit 100 includes a dielectric layer 116 on the dielectric layer 114, in accordance with some embodiments. In some embodiments, the dielectric layer 116 includes SiOC. In some embodiments, the dielectric layer is deposited by CVD, ALD, or PVD. In some embodiments, the dielectric layer 116 has a thickness between 10 nm and 50 nm. Other materials, deposition processes, and thicknesses can be utilized for the dielectric layer 116 without departing from the scope of the present disclosure.

In FIG. 1, a layer of photoresist 118 has been formed on the dielectric layer 116, in accordance with some embodiments. The layer of photoresist 118 includes a material having a composition that changes on exposed to photolithography light. In some embodiments, the layer of photoresist 118 includes a material that is sensitive to extreme ultraviolet (EUV) radiation from about 13.5 nm. In some embodiments, the layer of photoresist 118 includes a positive photoresist. In some embodiments, the layer of photoresist 118 includes an organic photoresist.

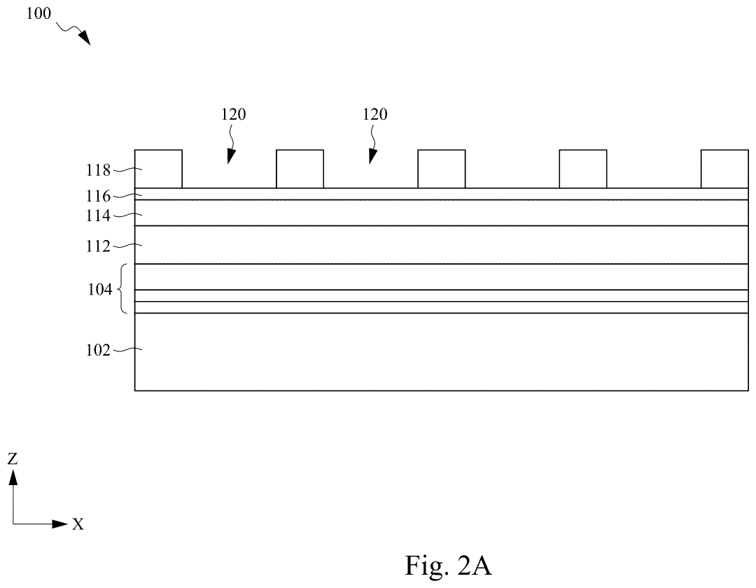

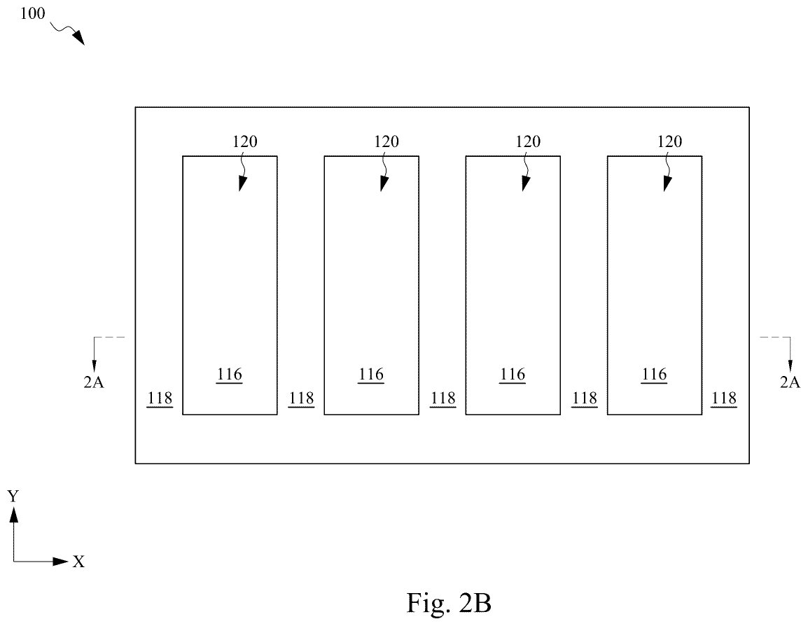

In FIG. 2A, a photolithography process has been performed. The photolithography process includes exposing the layer of photoresist 118 to photolithography light including the pattern of the reticle. After the exposure, the exposed portions of the layer of photoresist 118 are removed, resulting in a pattern of the trenches 120 in the layer of photoresist 118. The pattern of the trenches 120 corresponds to the pattern of the reticle. As will be set forth in more detail below, this pattern of trenches 120 will be utilized to form an initial set of tracks in the patterning layer 112.

FIG. 2B is a top view of the integrated circuit 100 at the stage of processing shown in FIG. 2A, in accordance with some embodiments. The cross-sectional view of FIG. 2A is taken along cut lines 2A of FIG. 2B. The top view of FIG. 2B illustrates the rectangular trenches 120 formed in the layer of photoresist 118. The top surface of the dielectric layer 116 is exposed in the trenches 120. Although FIG. 2B illustrates the trenches 120 having rectangular ends, in some embodiments the trenches 120 have rounded ends.

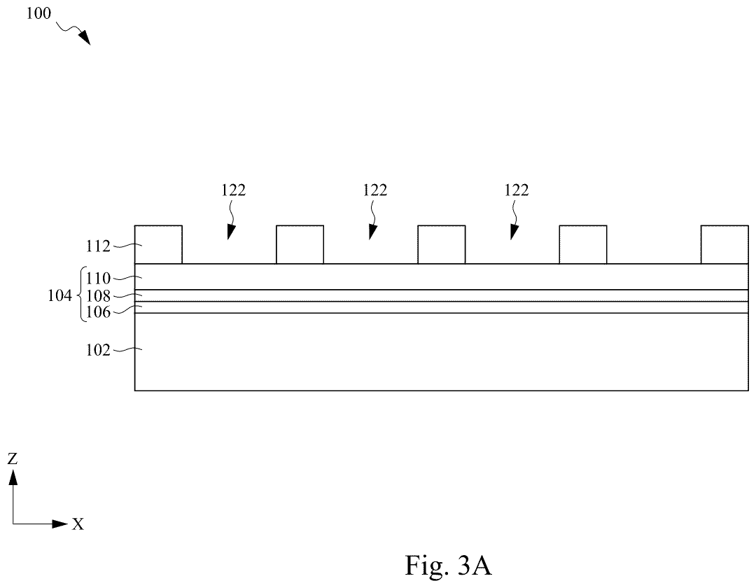

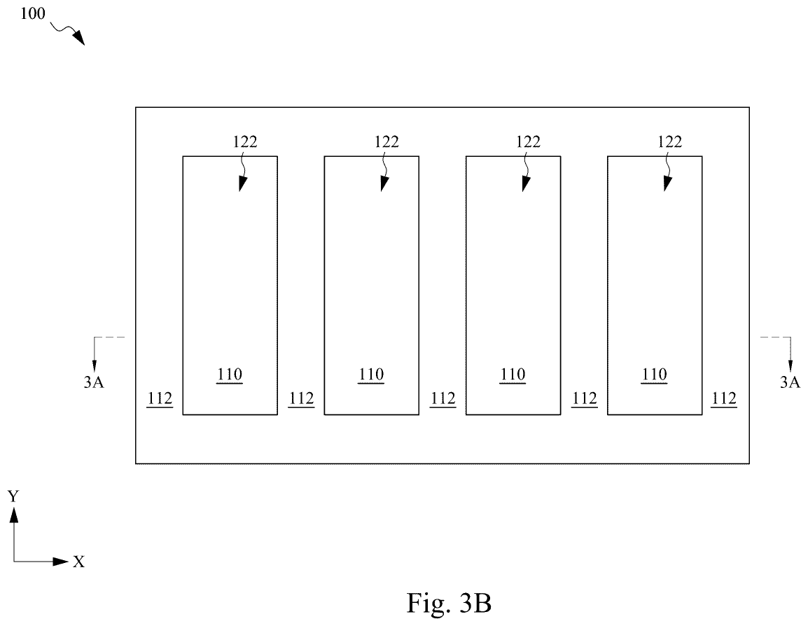

FIG. 3A is a cross-sectional view of the integrated circuit 100, in accordance with some embodiments. In FIG. 3A, an etching process has been performed in the presence of the patterning the layer of photoresist 118. In particular, tracks 122 have been formed in the patterning layer 112. The tracks 122 have the pattern of the tracks 120 of the photoresist layer 118. An etching process has been performed to etch the dielectric layers 114 and 116 in the downward direction at the locations exposed by the tracks 120. The etching process continues and the patterning layer 120 is also etched in the downward direction at the locations exposed by the tracks 120. The result is that tracks 122 are formed in the patterning layer 112. The top surface of the hard mask some layer 110 is exposed at the bottom of the tracks 122. The tracks 122 may also be termed trenches in the patterning layer 112.

In some embodiments, a single etching process is performed to etch through the dielectric layers 116 and 114 and the patterning layer 112. In some embodiments, multiple separate etching steps are performed to etch through the dielectric layers 116 and 114 and the patterning layer 112. The final etching step selectively etches the patterning layer 112 with respect to the hard mask some layer 110. The result is that the etching process stops at the top surface of the hard mask some layer 110 without substantially etching the hard mask layer 110. The etching process can include one or more dry etching steps that anisotropically etch in the downward direction.

FIG. 3B is a top view of the integrated circuit 100 at the stage of processing shown in FIG. 3A, in accordance with some embodiments. The cross-sectional view of FIG. 3A is taken along cut lines 3A of FIG. 3B. The top view of FIG. 3B illustrates the tracks 122 formed in the layer of patterning layer 122. The top surface of the hard mask some layer 110 is exposed in the tracks 122. Although FIG. 3B illustrates the tracks 122 as having rectangular ends, in some embodiments the tracks 122 have rounded ends.

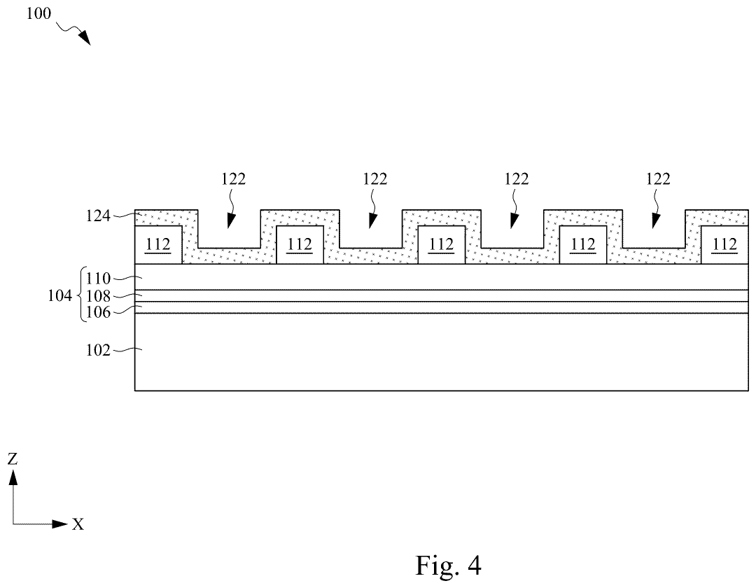

In FIG. 4, a dielectric layer 124 has been deposited on the integrated circuit 100, in accordance with some embodiments. The dielectric layer 124 is conformally deposited on the top surface of the patterning layer 112, on sidewalls of the patterning layer 112, and on the top surface of the hard mask sublayer 110. In some embodiments, the dielectric layer 124 includes a material that is selectively etchable with respect to the material of the patterning layer 112 and the hard mask sublayer 110. In some embodiments, the dielectric layer 124 includes SiON, SiN, SiC, SiOC, SiOCN, SiO, or other suitable materials. The dielectric layer 124 has a thickness between 8 nm and 15 nm, corresponding to a vertical thickness of the dielectric layer 124 on the top surfaces of the patterning layer 112 and a lateral thickness on the sidewalls of the patterning layer 112. The dielectric layer 124 can be deposited by CVD, ALD, or PVD. Other materials, thicknesses, and deposition processes can be utilized for the dielectric layer 124 without departing from the scope of the present disclosure.

The dielectric layer 124 is a spacer layer. As will be set forth in more detail below, the dielectric layer 124 will be patterned to form spacers on the sidewalls of the tracks 122. The spacers will be utilized to form the pattern of the first group of metal lines and the second group of metal lines, laterally interleaved with the first group of metal lines.

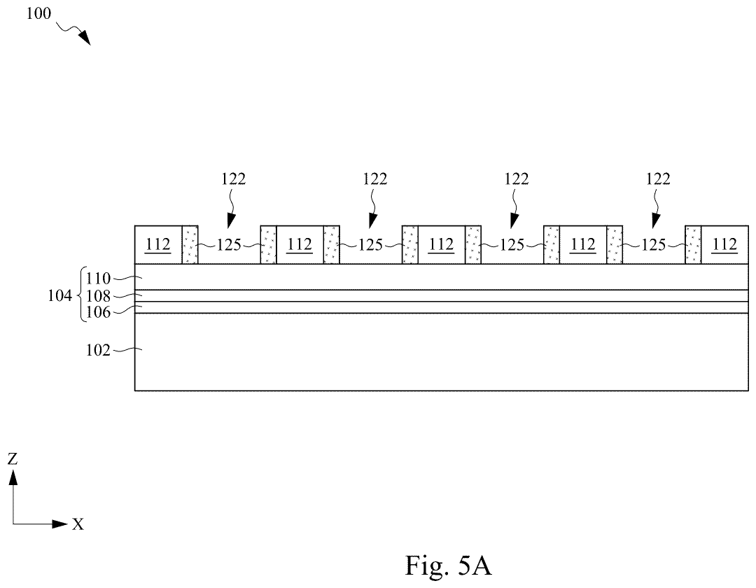

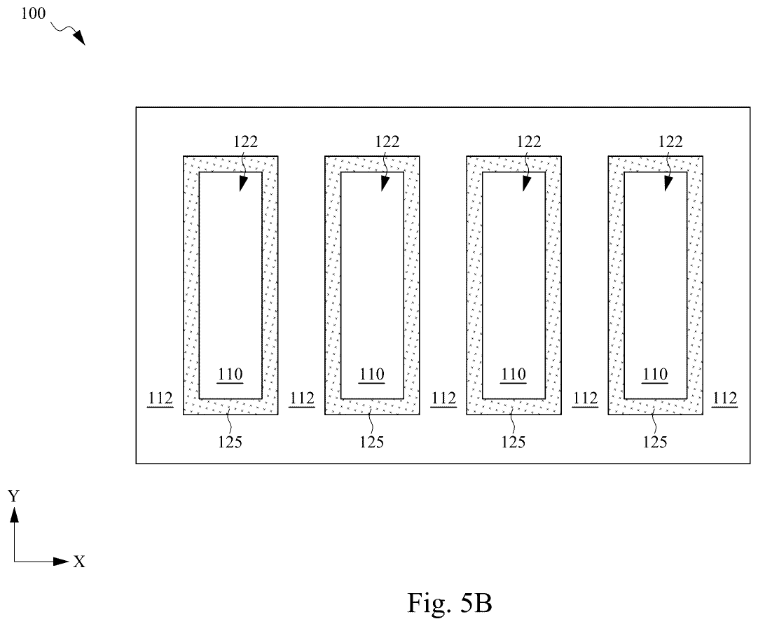

FIG. 5A is a cross-sectional view of the integrated circuit 100, in accordance with some embodiments. In FIG. 5A, an etching process has been performed in the presence of the patterning the dielectric layer 124. In particular, spacers 125 have been formed from the dielectric layer 124 on the sidewalls of the patterning layer 112, corresponding to the sidewalls of the tracks 122. The etching process is an anisotropic etching process that etches in the downward direction. The etching process is a timed etching process with a timing selected to remove an amount of material. Corresponding to the vertical thickness of the dielectric layer 124 at the top surfaces of the patterning layer 112 and the hard mask sublayer 110. Because the vertical thickness of the dielectric layer 125 is smaller on the top surfaces of the patterning layer 112 and the hard mask sublayer 110 than on the sidewalls of the patterning layer 112, the dielectric layer 124 is entirely removed from the top surface of the patterning layer 112 and from the central portions of the exposed top surfaces of the hard mask sublayer 110 without removing the dielectric layer 124 from the sidewalls of the patterning layer 112. The result is that spacers 125 are formed from the dielectric layer 124 on the sidewalls of the patterning layer 112. Portions of the top surface of the hard mask sublayer 110 are exposed in the tracks 122.

The formation of the spacers 125 defines the general pattern of the first group of metal lines and the second group of metal lines for the interlevel dielectric layer 102. In particular, the first group of metal lines will be formed below the location of the tracks 122. The second group of metal lines will be formed below the location of the remaining portions of the patterning layer 112. This is entirely defined by the location of the spacers 122.

FIG. 5B is a top view of the integrated circuit 100 at the stage of processing shown in FIG. 5A, in accordance with some embodiments. The cross-sectional view of FIG. 5A is taken along cut lines 5A of FIG. 5B. The top view of FIG. 5B illustrates the spacers 125 lining and laterally enclosing the tracks 122. The top surface of the hard mask some layer 110 is exposed in the tracks 122.

As can be seen in the top view of FIG. 5A, each spacer 125 encloses an area corresponding to a track 122, in accordance with some embodiments. In some embodiments, the enclosed areas are rectangular. In some embodiments, the enclosed areas are elliptical. The enclosed areas correspond to the location below which the first group of metal lines will be formed in the interlevel dielectric layer 102. The areas 123 between the enclosed areas corresponds to the locations below which the second group of metal lines will be formed in the interlevel dielectric layer 102.

As described above, the area below each region enclosed by a spacer 125 will be utilized to form one of the first metal lines. However, in practice, multiple first metal lines separated from each other in the Y direction may be formed below each enclosed area, as will be described in further detail below. Similarly, multiple second metal lines separated from each other in the Y direction may be formed below each area 123 between adjacent spacers 125.

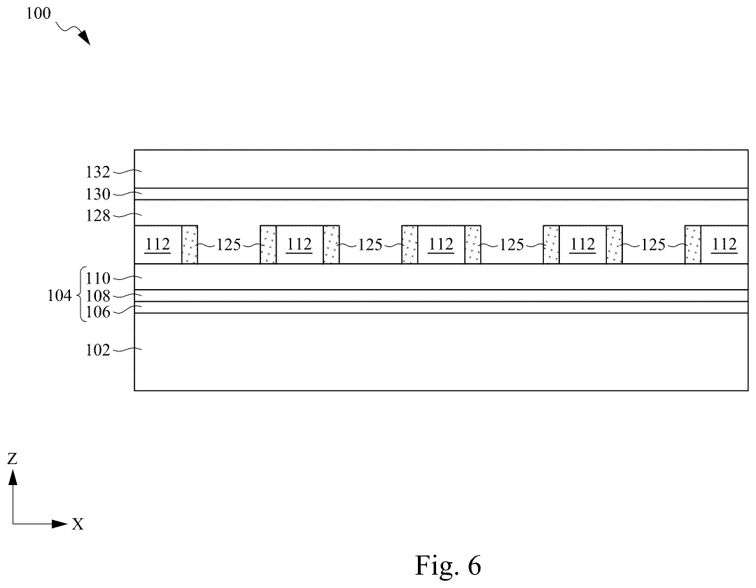

FIG. 6 is a cross-sectional view of the integrated circuit 100, in accordance with some embodiments. In FIG. 6, a dielectric layer 128, a dielectric layer 130, and a layer of photoresist 132 have been formed in preparation for a second photolithography process. The second photolithography process will be utilized to define the lengths (in the Y-direction) and positions of the first metal lines.

The dielectric layer 128 is formed on the patterning layer 112, on the spacers 125, and on exposed portions of the top surface of the hard mask sublayer 110. In some embodiments, the dielectric layer 128 includes amorphous carbon. In some embodiments, the dielectric layer is deposited by CVD, ALD, or PVD. In some embodiments, the dielectric layer 128 has a thickness between 10 nm and 50 nm. Other materials, deposition processes, and thicknesses can be utilized for the dielectric layer 128 without departing from the scope of the present disclosure.

The dielectric layer 130 is formed on the dielectric layer 128, in accordance with some embodiments. In some embodiments, the dielectric layer 130 includes SiOC. In some embodiments, the dielectric layer 130 is deposited by CVD, ALD, or PVD. In some embodiments, the dielectric layer 130 has a similar thickness as the dielectric layer 116. Other materials, deposition processes, and thicknesses can be utilized for the dielectric layer 130 without departing from the scope of the present disclosure.

The layer of photoresist 132 has been formed on the dielectric layer 130, in accordance with some embodiments. The layer of photoresist 130 is a same material as the layer of photoresist 118 of FIG. 1.

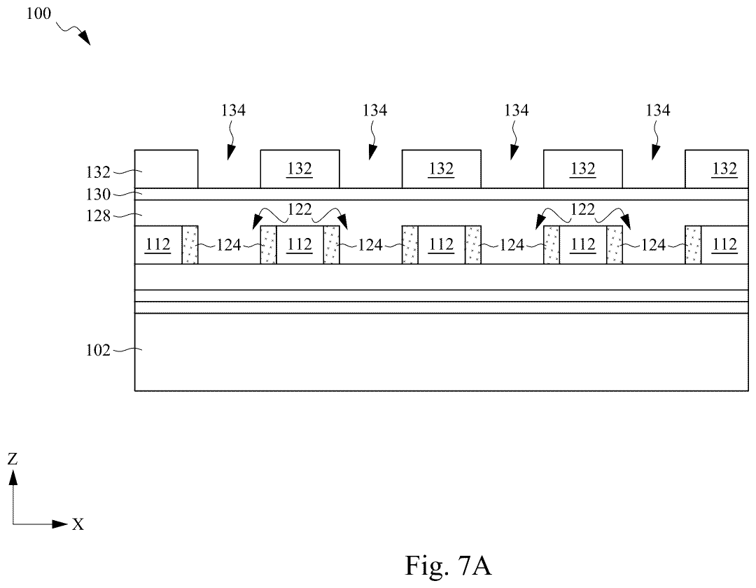

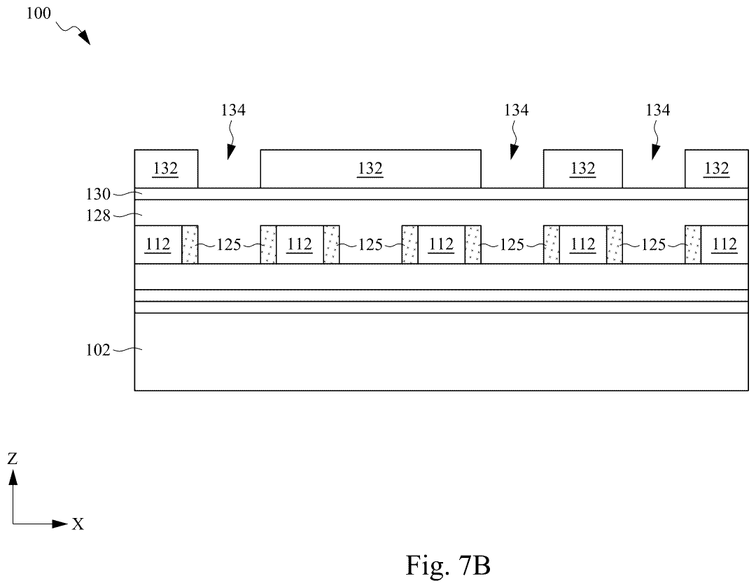

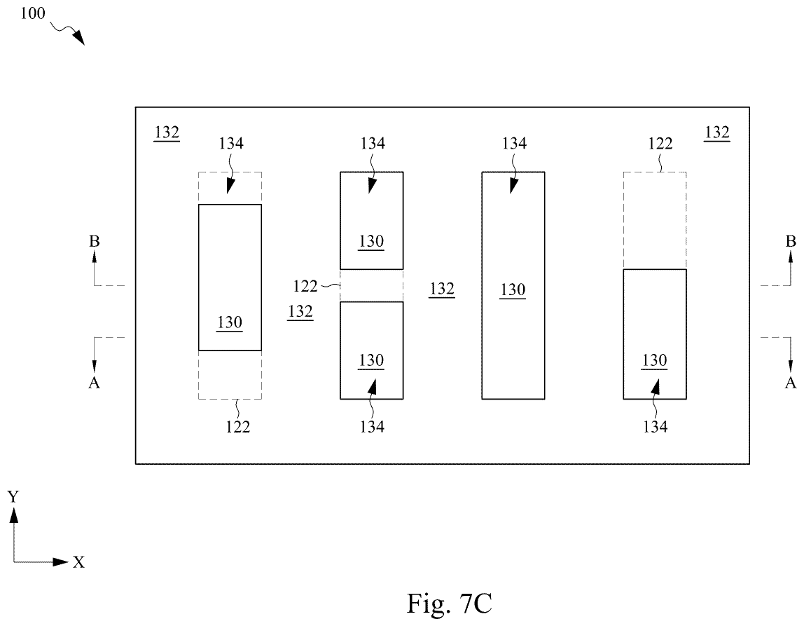

FIG. 7A is a cross-sectional view of the integrated circuit 100, in accordance with some embodiments. In FIG. 7A, a photolithography process has been performed. The photolithography process includes exposing the layer of photoresist 132 to photolithography light including the pattern of a reticle. After the exposure, the exposed portions of the layer of photoresist 132 are removed, resulting in a pattern of the trenches 134 in the layer of photoresist 132. The pattern of the trenches 132 corresponds to the pattern of the reticle.

FIG. 7A illustrates the trenches 134 as having a same width in the X direction as the trenches 122. However, in some embodiments, the trenches 134 are wider than the trenches 122. The trenches 134 overlap with the spacers 125. Because the subsequent etching process will not etch the spacers 125, there is some leeway in the layout of the trenches 134. This can help relax the alignment specifications of the layout of the trenches 134 because subsequent trenches will be self-aligned with the spacers 125, or with the trenches 122.

FIG. 7B is a cross-sectional view of the integrated circuit 100 at the same stage of processing shown in FIG. 7A, in accordance with some embodiments. The cross-sectional view of FIG. 7A is taken along cut lines 7A, as shown in the top view of FIG. 7C. The cross-sectional view of FIG. 7B is taken along cut lines 7B, as shown in the top view of FIG. 7C. FIG. 7C includes dashed lines indicating the locations of the tracks 122 below the layer of photoresist 132.

FIGS. 7B and 7C illustrate that the trenches 134 do not extend in the Y direction through the entire length of each track 122. Instead, each trench 134 corresponds to the pattern of a single first metal line. For the left-most track 122, a single trench 134 is formed corresponding to the pattern of a single first metal line. For the second track 122 from the left, two trenches 134 are formed and separated from each other in the Y direction and corresponding to the pattern of two first metal lines. For the track 122 second from the right, a single trench 134 is formed corresponding to the pattern of a single first metal line. For the right-most track 122, a single trench 134 is formed corresponding to the pattern of a single first metal line.

As will be set forth in more detail below, the ends (in the Y-direction) of each trench 134 are patterned without the use of a separate mask to form cuts or breaks to separate adjacent metal lines. The result is that the ends of adjacent first metal lines can be very close together. Furthermore, the ends of first metal lines can be as far from the ends of the tracks 122 as desired. This results in less extraneous or redundant metal. The first metal lines can be substantially exactly as long (or short) as desired.

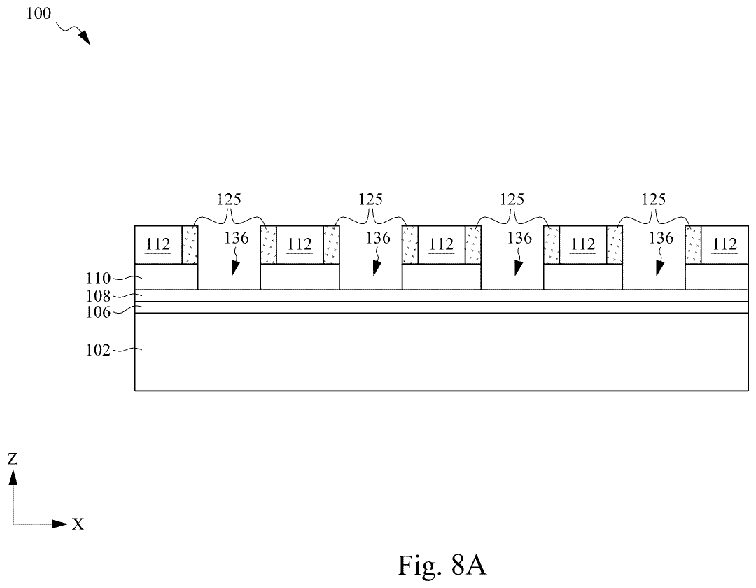

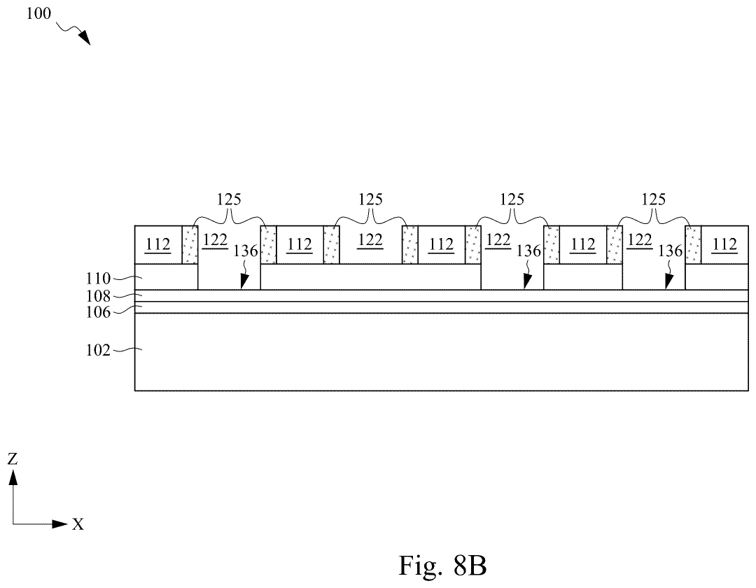

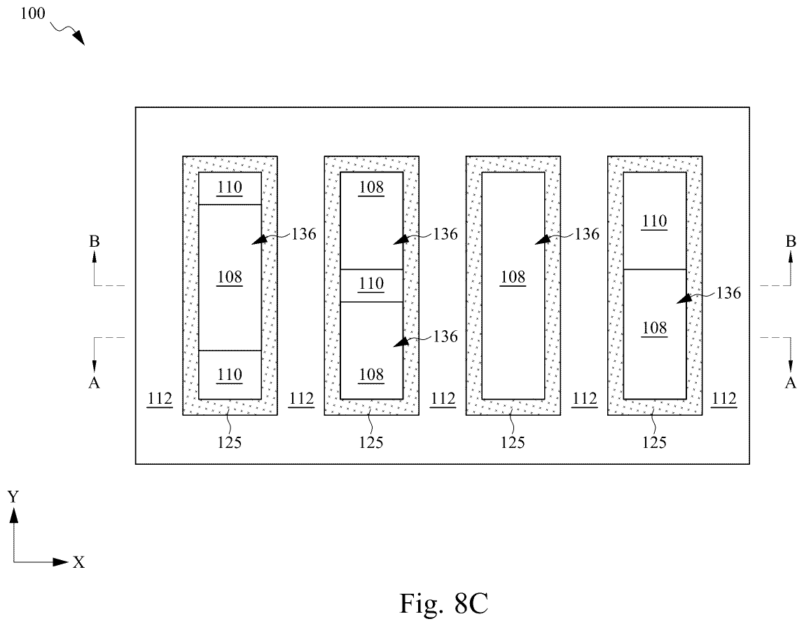

FIGS. 8A and 8B are cross-sectional views of the integrated circuit 100, in accordance with some embodiments. FIG. 8C is a top view of the integrated circuit 100, in accordance with some embodiments. The cross-sectional views of FIGS. 8A and 8B are taken along cut lines 8A and 8B, respectively, in FIG. 8C.

An etching process has been performed in the presence of the patterned layer of photoresist 132. The etching process etches the dielectric layers 130 and 128 at the locations exposed by the trenches 134. The etching process also etches the hard mask sublayer 110 at locations exposed by the trenches 134. The etching process is an anisotropic etching process that selectively etches in the downward direction. In some embodiments, the etching process includes a single etching step that etches through the dielectric layers 128 and 134 and the hard mask sublayer 110. In some embodiments, the etching process includes multiple etching steps to separately etched through the various layers. The etching process selectively etches the exposed portions of the layers without substantially etching the spacers 125.

The end result of the etching process is that trenches 136 are formed in the hard mask sublayer 110 in the pattern of the trenches 134 of the photoresist layer 132. Each trench 136 exposes the top surface of the hard mask sublayer 108. Each trench 136 corresponds to the pattern and location of an individual first metal line that will be formed in the interlevel dielectric layer 102. As described previously in relation to FIGS. 7A-7C, some tracks 122 correspond to the location of multiple first metal lines separated from each other in the Y direction. FIG. 8C illustrates this as trenches 136 separated by portions of the hard mask sublayer 110 that are not etched based on the pattern of the photoresist 132. FIG. 8C also illustrates how the locations of the ends trenches 136 can be selected without utilizing a separate mask for cutting or breaking.

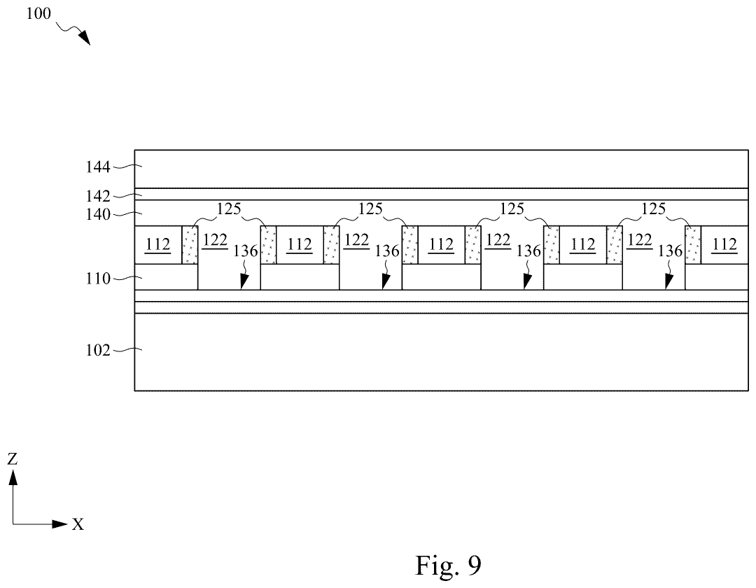

FIG. 9 is a cross-sectional view of the integrated circuit 100, in accordance with some embodiments. In FIG. 9, a dielectric layer 140, a dielectric layer 142, and the layer of photoresist 144 have been formed, in preparation for a third photolithography process. The third photolithography process will be utilized to define the lengths (in the Y-direction) and positions of the second metal lines.

The dielectric layer 140 is formed on the patterning layer 112, on the spacers 125, on exposed sidewalls of the hard mask sublayer 110, and on exposed portions of the top surface of the hard mask sublayer 108. In some embodiments, the dielectric layer 140 includes amorphous carbon. In some embodiments, the dielectric layer is deposited by CVD, ALD, or PVD. In some embodiments, the dielectric layer 140 has a thickness between 10 nm and 50 nm. Other materials, deposition processes, and thicknesses can be utilized for the dielectric layer 140 without departing from the scope of the present disclosure.

The dielectric layer 142 is formed on the dielectric layer 140, in accordance with some embodiments. In some embodiments, the dielectric layer 142 includes SiOC. In some embodiments, the dielectric layer 142 is deposited by CVD, ALD, or PVD. In some embodiments, the dielectric layer 142 has a similar thickness as the dielectric layer 116. Other materials, deposition processes, and thicknesses can be utilized for the dielectric layer 142 without departing from the scope of the present disclosure.

The layer of photoresist 144 has been formed on the dielectric layer 142, in accordance with some embodiments. The layer of photoresist 142 has a similar material as the layer of photoresist 118 of FIG. 1.

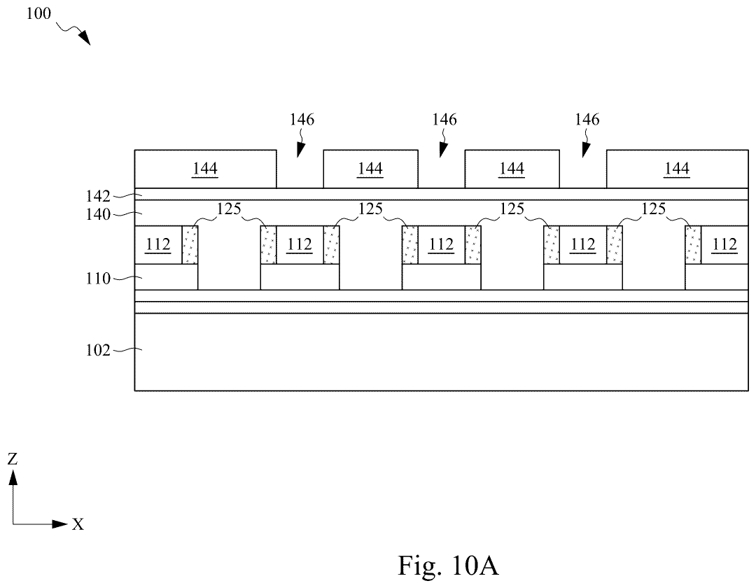

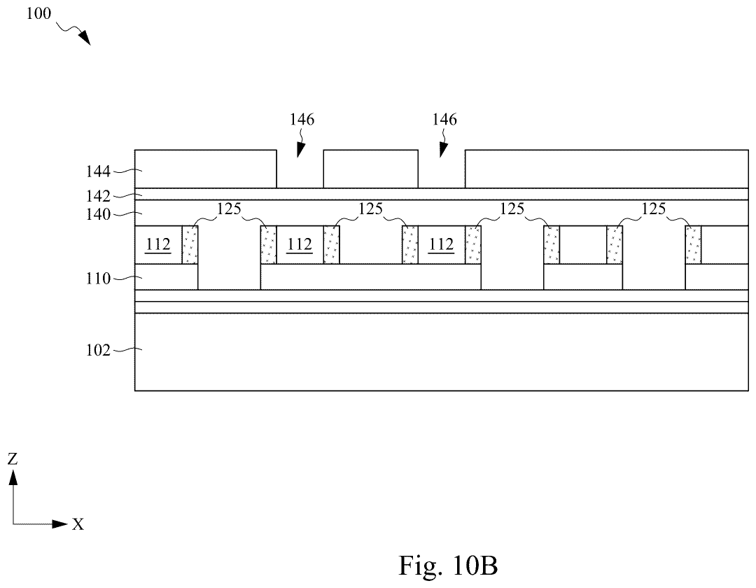

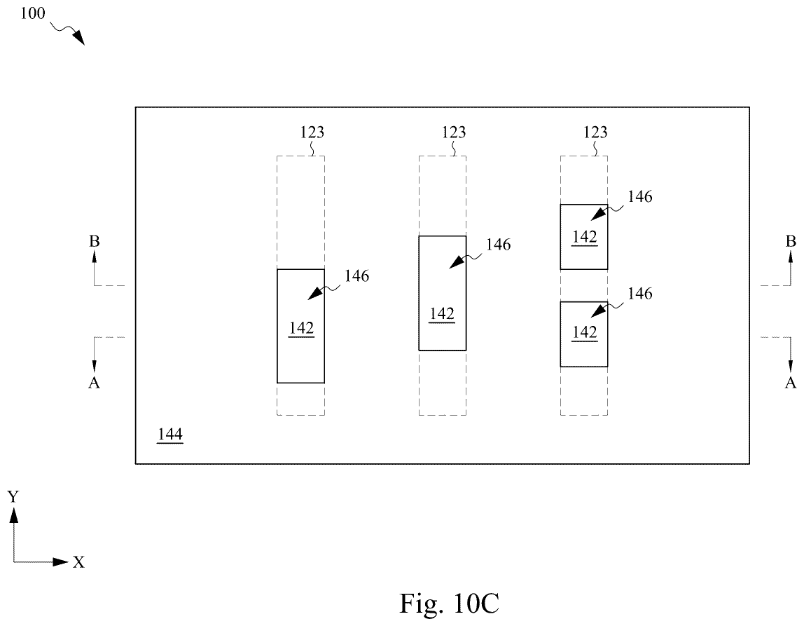

FIG. 10A is a cross-sectional view of the integrated circuit 100, in accordance with some embodiments. In FIG. 10A, a photolithography process has been performed. The photolithography process includes exposing the layer of photoresist 144 to photolithography light including the pattern of a reticle. After the exposure, the exposed portions of the layer of photoresist 144 are removed, resulting in a pattern of the trenches 146 in the layer of photoresist 144. The pattern of the trenches 146 corresponds to the pattern of the reticle.

FIG. 10A illustrates the trenches 146 as having a same width in the X direction as the portions 112 of the patterning layer 112 below the trenches 146. However, in some embodiments, the trenches 146 are wider than the portions of the patterning layer 112. The trenches 146 overlap with the spacers 125. Because the subsequent etching process will not etch the spacers 125, there is some leeway in the layout of the trenches 146. This can help relax the alignment specifications of the layout of the trenches 146 because subsequent trenches will be self-aligned with the spacers 125, or with the regions 123 between the spacers 125.

FIG. 10B is a cross-sectional view of the integrated circuit 100 at the same stage of processing shown in FIG. 10A, in accordance with some embodiments. The cross-sectional view of FIG. 10A is taken along cut lines 10A, as shown in the top view of FIG. 10C. The cross-sectional view of FIG. 10B is taken along cut lines 10B, as shown in the top view of FIG. 10C. FIG. 10C includes dashed lines indicating the locations of the regions 123 corresponding to the areas between spacers 125 below the layer of photoresist 144.

FIGS. 10B and 10C illustrate that the trenches 146 do not extend in the Y direction through the entire length of each region 123. Instead, each trench 146 corresponds to the pattern of a single second metal line. For the left most region 123, a single trench 146 is formed corresponding to the pattern of a single second metal line. For the middle region 123, a single trench 146 is formed, corresponding to the location of a single second metal line. For the right region 123, two trenches 146 are formed separated from each other in the Y direction and corresponding to the pattern of two second metal lines.

As will be set forth in more detail below, the ends (in the Y-direction) of each trench 146 are patterned without the need of a separate mask to form cuts or breaks to separate adjacent metal lines. The result is that the ends of adjacent second metal lines can be very close together. Furthermore, the ends of second metal lines can be as far from the ends of the regions 123 as desired. This results in less extraneous or redundant metal. The second metal lines can be substantially exactly as long (or short) as desired.

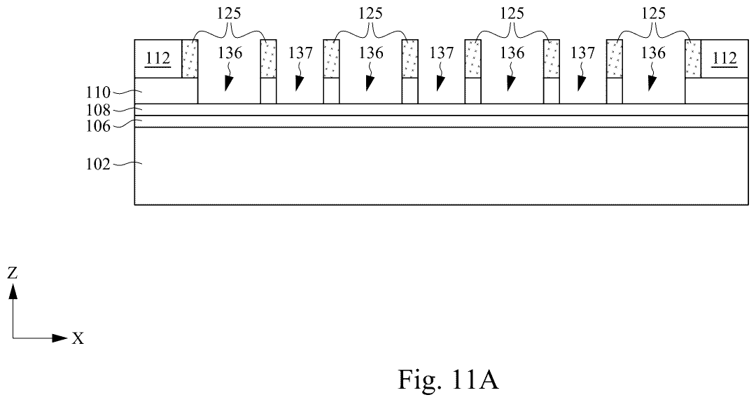

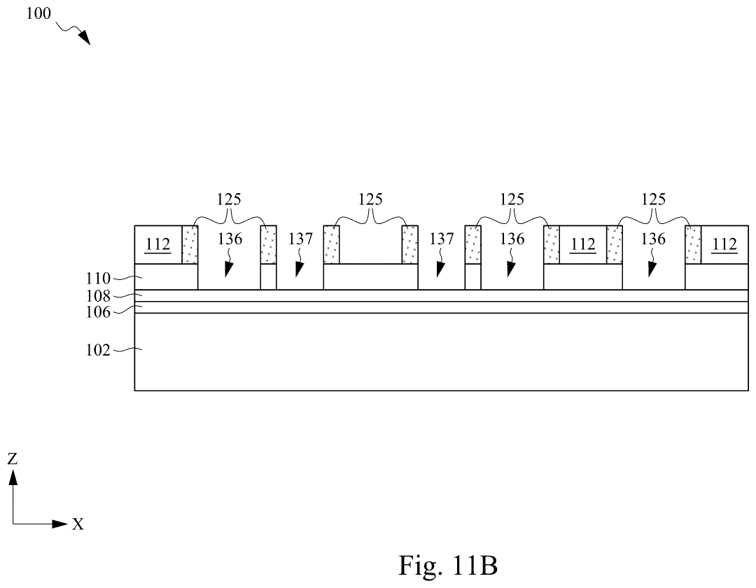

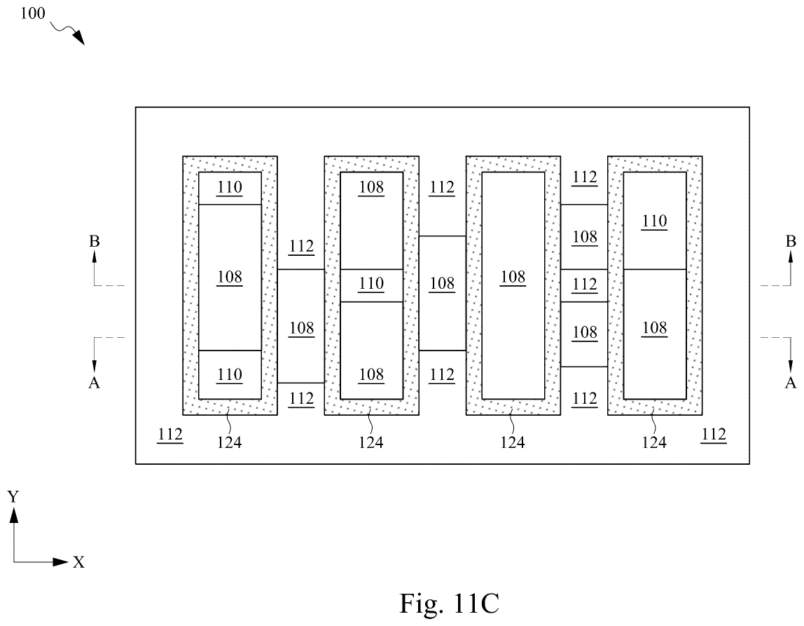

FIGS. 11A and 11B are cross-sectional views of the integrated circuit 100, in accordance with some embodiments. FIG. 11C is a top view of the integrated circuit 100, in accordance with some embodiments. The cross-sectional views of FIGS. 11A and 11B, are taken along cut lines 11A and 11B, respectively, in FIG. 11C.

An etching process has been performed in the presence of the patterned layer of photoresist 144. The etching process etches the dielectric layers 142 and 140 at the locations exposed by the trenches 146. The etching process also etches the patterning layer 112 and the hard mask sublayer 110 at locations exposed by the trenches 146. The etching process is an anisotropic etching process that selectively etches in the downward direction. In some embodiments, the etching process includes a single etching step that etches through the dielectric layers 140 and 146, the patterning layer 112, and the hard mask sublayer 110. In some embodiments, the etching process includes multiple etching steps to separately etch through the various layers. The etching process selectively etches the exposed portions of the layers without substantially etching the spacers 125.

The end result of the etching process is that trenches 137 are formed in the hard mask sublayer 110 in the pattern of the trenches 146 of the photoresist layer 144. Each trench 137 exposes the top surface of the hard mask sublayer 108. Each trench 137 corresponds to the pattern and location of an individual second metal line that will be formed in the interlevel dielectric layer 102. As described previously in relation to FIGS. 10A-10C, some regions 123 correspond to the location of multiple second metal lines separated from each other in the Y direction. FIG. 11C illustrates this as trenches 137 separated by portions of the patterning layer 112 and hard mask sublayer 110 that are not etched based on the pattern of the photoresist 144. FIG. 11C also illustrates how the locations of the ends trenches 137 can be selected without utilizing a separate mask for cutting or breaking.

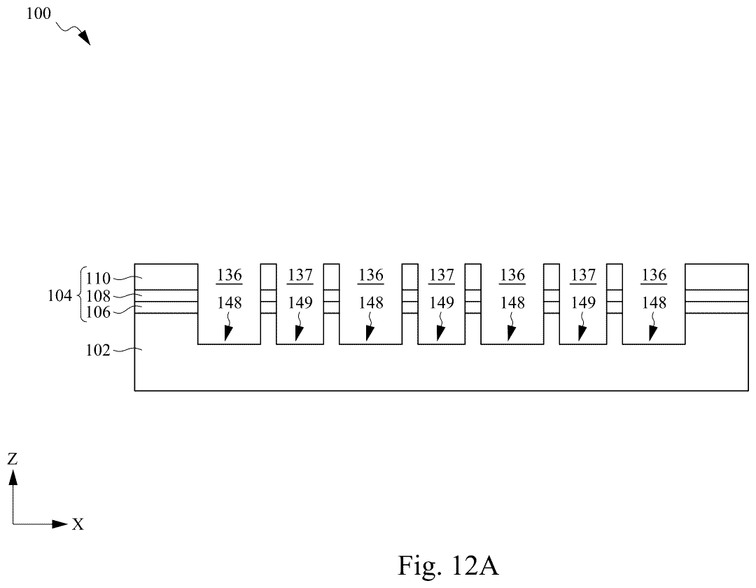

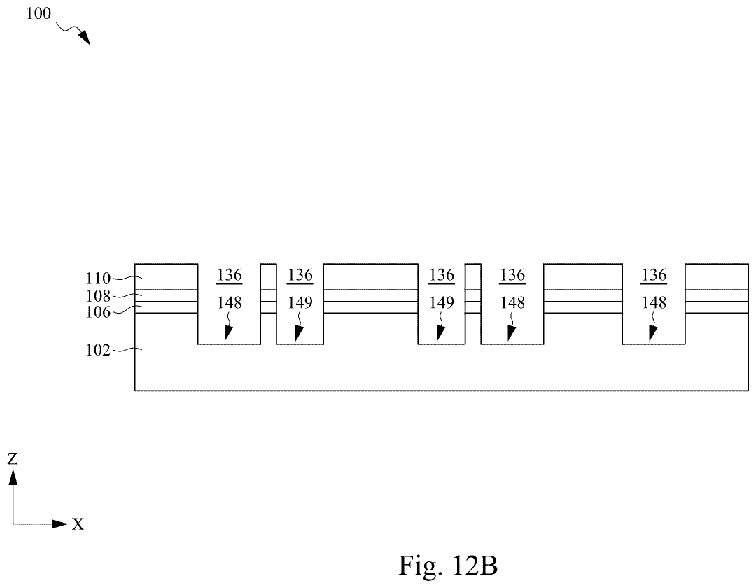

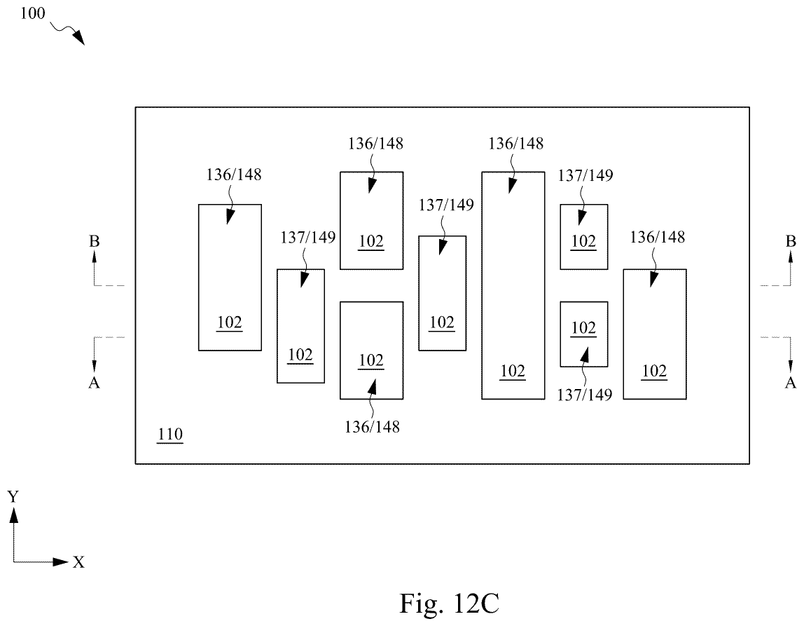

FIGS. 12A and 12B are cross-sectional views of the integrated circuit 100, in accordance with some embodiments. FIG. 12C is a top view of the integrated circuit 100. The cross-sectional views of FIGS. 12A and 12B, are taken along cut lines 12A and 12B, respectively, from FIG. 12C.

In FIGS. 12A-12C, an etching processes been performed, in accordance with some embodiments. The hard mask layer 104 has been fully patterned in accordance with the trenches 136 and 137 described in relation to FIGS. 11A-11C. In other words, the trenches 136 and 137 have been extended fully through the hard mask sublayers 108 and 106. The etching process further forms trenches 148 in the interlevel dielectric layer 102 in the pattern of the trenches 136 by extending the trenches 136 into the interlevel dielectric layer 102. The etching process further forms trenches 149 in the interlevel dielectric layer 102 in the pattern of the trenches 137 by extending the trenches 137 into the interlevel dielectric layer 102. The same etching process forms the trenches 148 and 149. In some embodiments, the etching process includes multiple etching steps to etch through the hard mask sublayers 108 and 106 and the interlevel dielectric layer 102. In some embodiments, a single etching step is utilized to etch through the hard mask sublayers 108 and 106 and the interlevel dielectric layer 102.

The trenches 148 corresponds to the pattern of the trenches 134 extending into the interlevel dielectric layer 102. The trenches 148 correspond to the locations of the first metal lines. The trenches 149 corresponds to the pattern of the trenches 146 extending into the interlevel dielectric layer 102. The trenches 149 correspond to the locations of the second metal lines.

In FIGS. 12A-12C, the spacers 125 have been removed. Any remaining portions of the patterning layer 112 have also been removed. This is accomplished by one or more etching steps. The result is that in FIGS. 12A-12C only the fully patterned hard mask layer 104 remains above the interlevel dielectric layer 102.

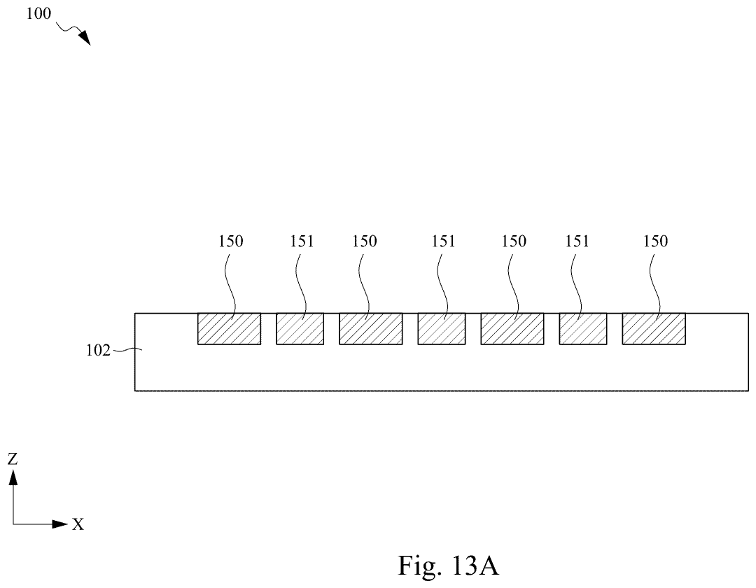

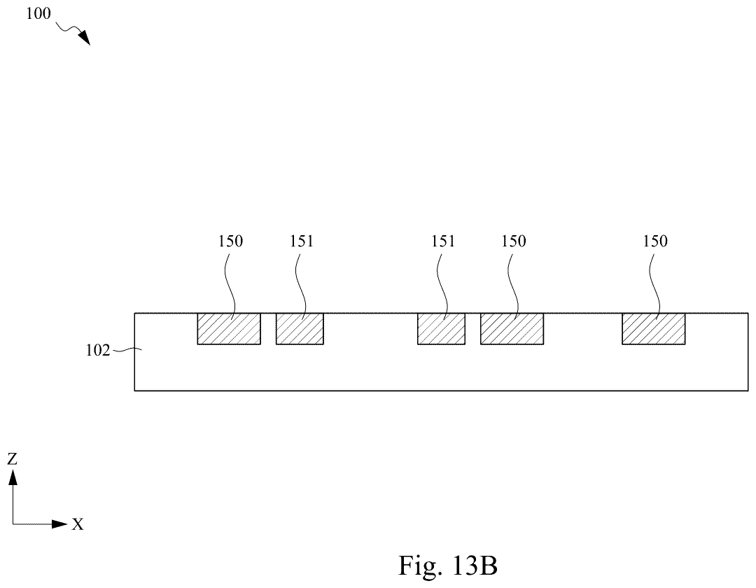

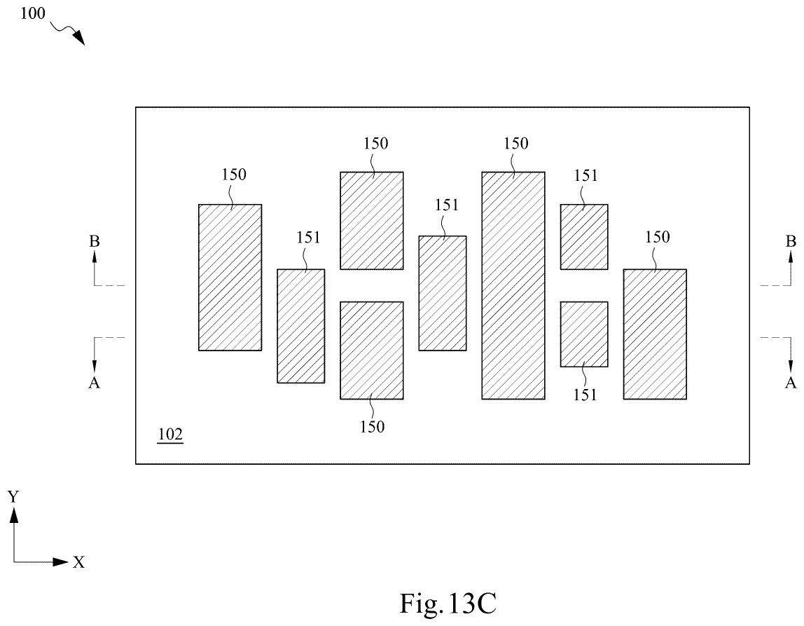

FIGS. 13A and 13B are cross-sectional views of the integrated circuit 100, in accordance with some embodiments. FIG. 13C is a top view of the integrated circuit 100. The cross-sectional views of FIGS. 13A and 13B, are taken along cut lines 13A and 13B, respectively, from FIG. 13C.

In FIGS. 13A-C, the hard mask layer 104 has been entirely removed. In some embodiments, the hard mask layer 104 is removed by performing one or more etching steps that selectively etch the materials of the hard mask sublayers with respect to the material of the interlevel dielectric layer 102. In some embodiments, the hard mask layer 104 is removed by performing a CMP process.

In FIGS. 13A-C, the first metal lines 150 and the second metal lines 151 have been formed in the interlevel dielectric layer 102. The first and second metal lines 150 and 151 are formed by depositing one or more metals in the trenches 148 and 149. The one or more metals can include one or more liner layers that line the sidewalls and bottom of the trenches 148 and 149. The one or more liner layers can include TiN, TaN, or other suitable materials. In some embodiments, the one or more metals include a metal deposited on the liner layer and that fills the trenches 148 and 149. The metal can include W, Ti, Ta, Al, Cu, Au, or other suitable conductive materials. The metal layers can be deposited by PVD, ALD, or CVD. After deposition of the one or more metals more metals, a CMP process is performed to remove excess metal material from the top surface of the interlevel dielectric layer 102. The result is the formation of the first metal lines 150 and the second metal lines 151.

The first metal lines 150 correspond to a group of first metal lines or a first group of metal lines. The second metal lines 151 correspond to a group of second metal lines or second group of metal lines. The metal lines 151 are laterally interleaved with the metal lines 150.

FIGS. 13A-13C illustrate the metal lines 150 is being wider in the X direction than the metal lines 151. However, in some embodiments, the metal lines 150 and 151 have a same width in the X direction. In some embodiments, the metal lines 150 and 151 each have a width between 10 nm and 50 nm, though other dimensions can be utilized without departing from the scope of the present disclosure. In some embodiments, the metal lines 150 and 151 are separated from each other by uniform distances in the X direction. In some embodiments, the separation distance in the X direction between adjacent metal lines 150 and 151 is between 5 nm and 50 nm, though other dimensions can be utilized without departing from the scope of the present disclosure.

The top view of FIG. 13C helps to illustrate some of the benefits of the process utilized to form the integrated circuit 100, in accordance with some embodiments. As can be seen in FIG. 13C, the metal lines have varying lengths in the Y direction. The portion of the interlevel dielectric layer 120 below each track 122 or region 123 is not occupied with extraneous metal material because the length of the metal lines 150/151 in the Y direction selected as any length. This results, in part, because the use of the spacers 125 enables avoiding photolithography processes devoted to form breaks or cuts in metal lines. Furthermore, due to the processes described above, metal lines 151 do not improperly widen in the X direction at locations where there is no adjacent metal line 150. This helps to reduce parasitic capacitance and avoids short circuits.

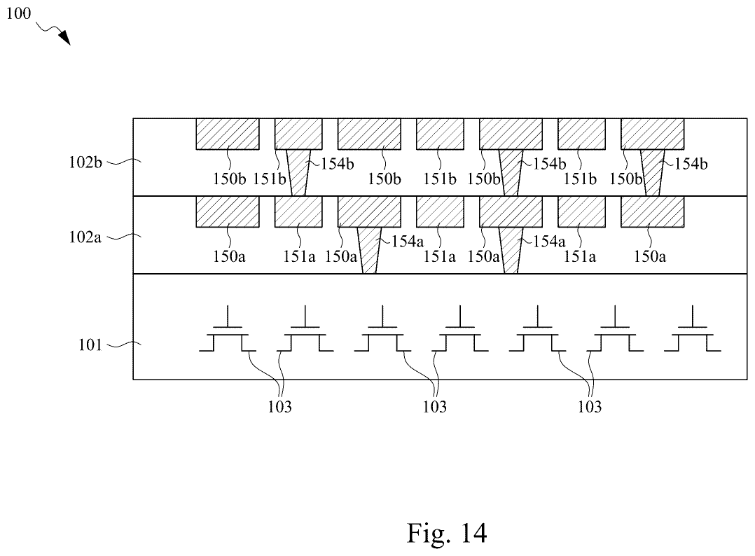

FIG. 14 is a cross-sectional view of an integrated circuit 100, in accordance with some embodiments. The integrated circuit 100 of FIG. 14 includes an active circuit region 101, a first interlevel dielectric layer 102a above the active circuit region 101, and a second interlevel dielectric layer 102b above the first interlevel dielectric layer 102a.

A plurality of transistors 103 are formed in the active circuit region 101, in accordance with some embodiments. The transistors 103 include PMOS transistors and NMOS transistors. In some embodiments, the transistors 103 are core logic circuits. In some embodiments, the transistors 103 makeup a portion of an SRAM array of the integrated circuit 100.

In some embodiments, the active circuit region 101 includes a semiconductor substrate. The channel regions and the source/drain regions of the transistors 103 are formed in conjunction with the semiconductor substrate. Gate dielectric layers and gate metals of the transistors are formed adjacent to the channel regions. Gate contacts, corresponding to conductive vias or conductive plugs, extend downward to contact the gate regions. Source/drain contacts, corresponding to conductive vias or conductive plugs extend downward to contact the source/drain regions. Various dielectric layers including gate spacers are formed over the transistor structures.

The interlevel dielectric layer 102a includes first metal lines 150a and second metal lines 151a formed, in accordance with the process described in relation to FIGS. 1-13C. Conductive vias 154a are formed in the interlevel dielectric layer 102a prior to formation of the metal lines 150a and 151a. The metal lines 150a/151a contact the conductive vias 154a at selected contact areas in accordance with a circuit layout. The conductive vias 154a provide electrical connection between the transistors 103 and the metal lines 150a/151a.

The interlevel dielectric layer 102b includes first metal lines 150b and second metal lines 151b formed in accordance with the process described in relation to FIGS. 1-13C. Conductive vias 154b are formed in the interlevel dielectric layer 102b prior to formation of the metal lines 150b and 151b. The conductive vias 154b contact the metal lines 150a/151a at selected contact locations in accordance with the circuit layout. The metal lines 150b/151bcontact the conductive vias 154b at selected contact areas in accordance with a circuit layout. The conductive vias 154b provide electrical between the metal lines 150b/151b and the metal lines 150a/151a. Additional interlevel dielectric layers and corresponding metal lines can be formed above the interlevel dielectric layer 102b.

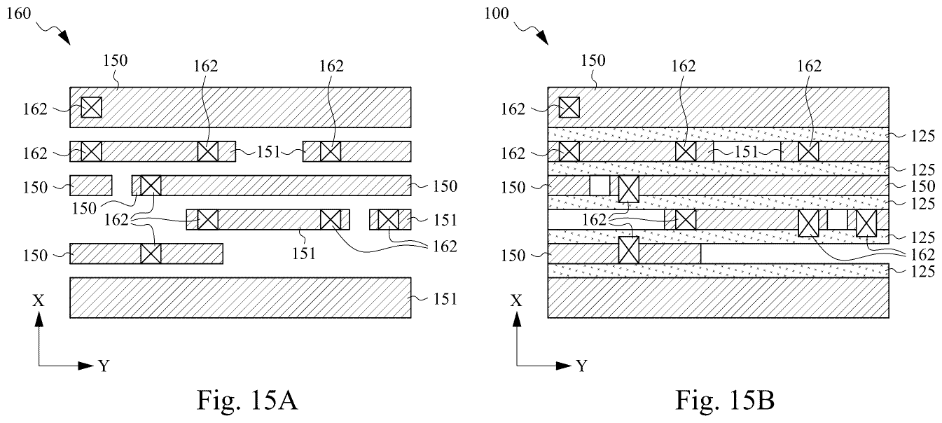

FIG. 15A is a top view of a layout 160 of metal lines for an integrated circuit, in accordance with some embodiments. The layout 160 corresponds to a stored design of metal lines. The layout 160 illustrates the planned locations of metal lines 150 and 151 and of contacts 162, corresponding to locations at which a metal line will contact a conductive via.

FIG. 15B is a top view of the integrated circuit 100 in which the layout 160 has been realized by the physical formation of metal lines 150 and 151 and contacts 162. The process described in relation to FIGS. 1-13C is utilized to form the metal lines 150 and 151. FIG. 15B also illustrates the location of the spacers 125, though, in practice, the spacers 125 are no longer present after formation of the metal lines 150 and 151. The use of the spacers 125 enables larger contact windows to be utilized.

As can be seen in FIG. 15B, the layout 160 is accurately implemented in the integrated circuit 100. There are multiple end-to-end spacings. The metal lines have uniform width and there is no enlargement in the Y-direction.

FIG. 16 is a top view of an integrated circuit 100, in accordance with some embodiments. FIG. 16 illustrates two first metal lines 150 and two second metal lines 151. FIG. 16 illustrates that both the first metal lines 150 and the second metal lines 151 have variable end-to-end distances, as indicated by the arrows. The end-to-end distances can correspond to the distance between adjacent metal lines 150/151 in the Y direction, or the distance between an end of a metal line 150/151 and an edge of the cell or track. Without the use of the confining spacers 125, the metal lines 150 may have limited end-to-end dimensions.

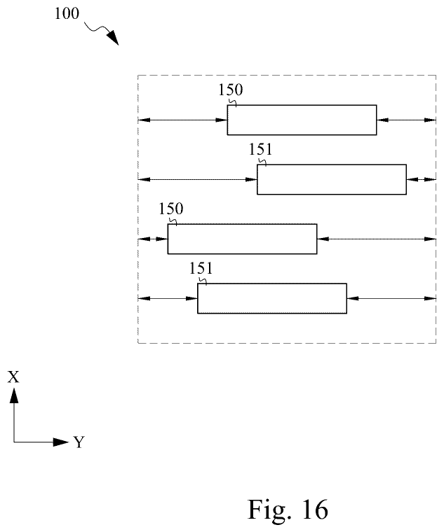

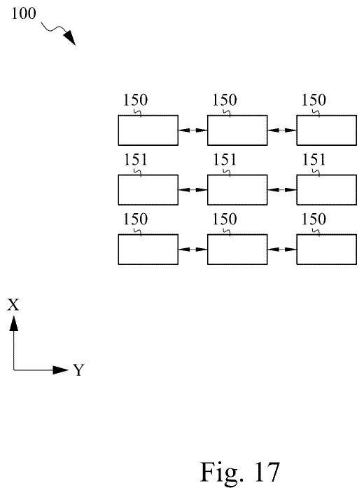

FIG. 17 is a top view of an integrated circuit 100, in accordance with some embodiments. FIG. 17 illustrates two sets of three first metal lines 150 and a set of three second metal lines 151. FIG. 17 illustrates that both the first metal lines 150 and the second metal lines 151 can have very small end-to-end separation utilizing the process described above.

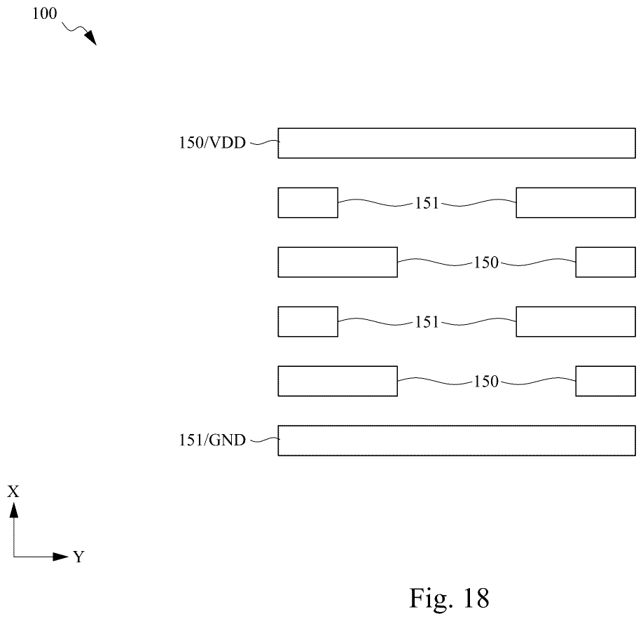

FIG. 18 is a top view of an integrated circuit 100, in accordance with some embodiments. FIG. 18 illustrates three first metal lines 150 and three second metal lines 151. As can be seen in FIG. 18, there is no widening of metal lines 151 in the X-direction where no metal line 150 is adjacent. This is because the use of the confining spacers 125 effectively prevents such widening. In some embodiments, the metal lines shown in FIG. 18 correspond to a portion of an SRAM cell, in which one of the metal lines 150 is a high supply voltage line supplying VDD and one of the metal lines 151 is a low supply voltage line supplying GND.

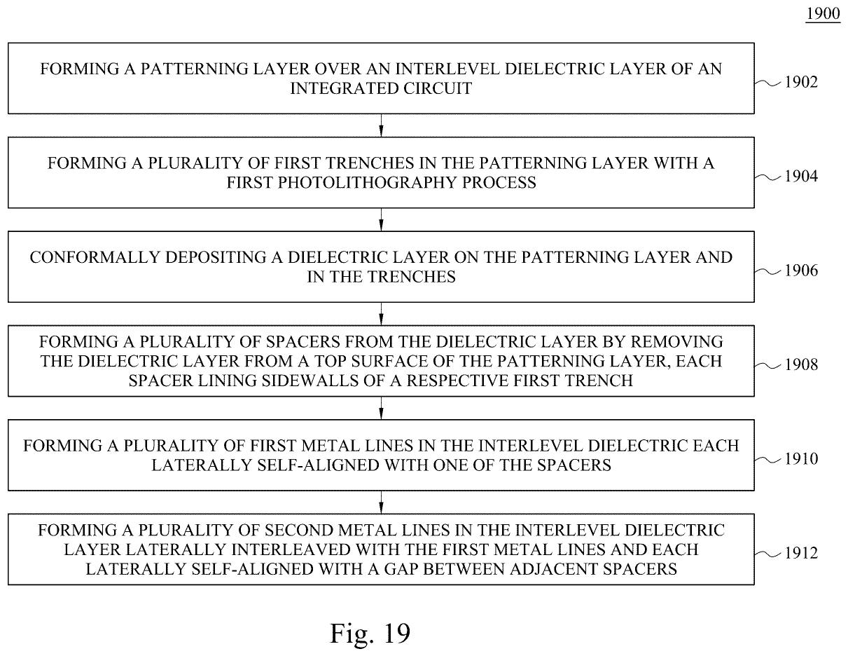

FIG. 19 is a flow diagram of a method 1900 for forming an integrated circuit, in accordance with some embodiments. The method 1900 can utilize processes, components, and structures described in relation to FIGS. 1-18. At 1902, the method 1900 includes forming a patterning layer over an interlevel dielectric layer of an integrated circuit. One example of an interlevel dielectric layer is the interlevel dielectric layer 102 of FIG. 1. One example of a patterning layer is the patterning layer 112 of FIG. 1. At 1904, the method 1900 includes forming a plurality of first trenches in the patterning layer with a first photolithography process. One example of first trenches are the first trenches 122 of FIG. 3A. At 1906, the method 1900 includes conformally depositing a dielectric layer on the patterning layer and in the trenches. One example of a dielectric layer is the dielectric layer 124 of FIG. 4. In 1908, the method 1900 includes forming a plurality of spacers from the dielectric layer by removing the dielectric layer from a top surface of the patterning layer, each spacer lining sidewalls of a respective first trench. One example of spacers are the spacers 125 of FIG. 5A. At 1910, the method 1900 includes forming a plurality of first metal lines in the interlevel dielectric each laterally self-aligned with one of the spacers. One example of first metal lines are the metal lines 150 of FIG. 13A. At 1912, the method 1900 includes forming a plurality of second metal lines in the interlevel dielectric layer laterally interleaved with the first metal lines and each laterally self-aligned with a gap between adjacent spacers. One example of second metal lines are the metal lines 151 of FIG. 13A.

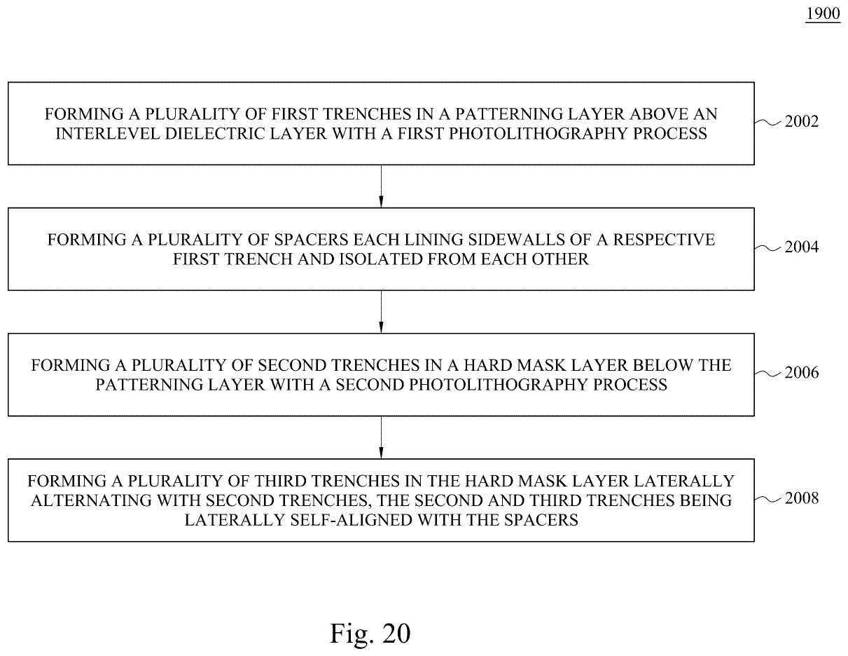

FIG. 20 is a flow diagram of a method 2000 for forming an integrated circuit, in accordance with some embodiments. The method 2000 can utilize processes, components, and structures described in relation to FIGS. 1-18. At 2002, the method 2000 includes forming a plurality of first trenches in a patterning layer above an interlevel dielectric layer with a first photolithography process. Of an interlevel dielectric layer is the interlevel dielectric layer 102 of FIG. 1. One example of a patterning layer is the patterning layer 112 of FIG. 1. One example of first trenches are the first trenches 122 of FIG. 3A. At 2004, the method 2000 includes forming a plurality of spacers each lining sidewalls of a respective first trench and isolated from each other. One example of spacers are the spacers 125 of FIG. 5A. At 2006, the method 2000 includes forming a plurality of second trenches in a hard mask layer below the patterning layer with a second photolithography process. One example of a hard mask layer is the hard mask layer 110 of FIG. 1. One example of second trenches are the trenches 136 of FIG. 8A. At 2008, the method 2000 includes forming a plurality of third trenches in the hard mask layer laterally alternating with second trenches, the second and third trenches being laterally self-aligned with the spacers. One example of third trenches are the trenches 137 of FIG. 11A.

Embodiments of the present disclosure provide a method for forming metal lines in an interlevel dielectric layer of an integrated circuit. The process forms a set of metal lines as a first group of metal lines and a second group of metal lines laterally interleaved with the first group of metal lines. The process forms a patterning layer over the interlevel dielectric layer. A first photolithography and etching process forms tracks in the patterning layer. A plurality of dielectric spacers are formed on sidewalls of the tracks, with the bottoms of the tracks exposed. A second photolithography and etching process forms a pattern of the first group of metal lines in the patterning layer, based on the dielectric spacers. A third photolithography and etching process forms a pattern of the second group of metal lines in the patterning layer, based on the dielectric spacers. The patterns of the first and second groups of metal lines are then transferred by an etching process to the interlevel dielectric layer as trenches in the interlevel dielectric layer. The first and second groups of the metal lines are then formed simultaneously by depositing a metal material in the trenches.

Embodiments of the present disclosure provide several benefits. First of all, there is no separate photolithography and etching process to form breaks in the metal lines. Secondly, in the patterning layer the trenches or windows for both the first group of metal lines and the second group of metal lines are confined by the dielectric spacers. This enables both groups of metal lines to have multiple end-to-end dimensions or small dimensions (e.g., very small end-to-end distances). There is also a tremendous reduction in excess line length and redundant metal. The lines do not have laterally enlarged characteristics at non-confined locations. This further results in better functioning integrated circuits and fewer scrapped wafers.

In some embodiments, a method includes forming a patterning layer over an interlevel dielectric layer of an integrated circuit and forming a plurality of first trenches in the patterning layer with a first photolithography process. The method includes conformally depositing a dielectric layer on the patterning layer and in the trenches and forming a plurality of spacers from the dielectric layer by removing the dielectric layer from a top surface of the patterning layer, each spacer lining sidewalls of a respective first trench. The method includes forming a plurality of first metal lines in the interlevel dielectric each laterally self-aligned with one of the spacers and forming a plurality of second metal lines in the interlevel dielectric layer laterally interleaved with the first metal lines and each laterally self-aligned with a gap between adjacent spacers.

In some embodiments, a method includes forming a plurality of first trenches in a patterning layer above an interlevel dielectric layer with a first photolithography process and forming a plurality of spacers each lining sidewalls of a respective first trench and isolated from each other. The method includes forming a plurality of second trenches in a hard mask layer below the patterning layer with a second photolithography process and forming a plurality of third trenches in the hard mask layer laterally alternating with second trenches, the second and third trenches being laterally self-aligned with the spacers.

In some embodiments, an integrated circuit includes a plurality of transistors, an interlevel dielectric layer above the transistors, and a plurality of first metal lines in the interlevel dielectric layer extending in a first lateral direction. The integrated circuit includes a plurality of second metal lines in the interlevel dielectric layer extending in the first lateral direction and alternating with the first metal lines in a second lateral direction transverse to the first lateral direction. The first metal lines have multiple different end-to-end dimensions. The second metal lines have multiple different end-to-end dimensions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a patterning layer over an interlevel dielectric layer of an integrated circuit;
forming a plurality of first trenches in the patterning layer with a first photolithography process;
conformally depositing a dielectric layer on the patterning layer and in the trenches;
forming a plurality of spacers from the dielectric layer by removing the dielectric layer from a top surface of the patterning layer, each spacer lining sidewalls of a respective first trench;
forming a plurality of first metal lines in the interlevel dielectric each laterally self-aligned with one of the spacers; and
forming a plurality of second metal lines in the interlevel dielectric layer laterally interleaved with the first metal lines and each laterally self-aligned with a gap between adjacent spacers.

2. The method of claim 1, comprising:
forming, in a hard mask layer between the patterning layer and the interlevel dielectric layer, a plurality of second trenches in the hard mask layer below the first trenches with a second photolithography process; and
forming, in the hard mask layer, a plurality of third trenches laterally interleaved with the first trenches based on the spacers with a third photolithography process.

3. The method of claim 2, wherein the second trenches are each below a respective first area enclosed by one of the spacers.

4. The method of claim 3, wherein the third trenches are each below respective second area between adjacent spacers.

5. The method of claim 2, wherein the second and third trenches extend partially into the hard mask layer.

6. The method of claim 2, comprising:
removing the spacers;
forming fourth trenches in the interlevel dielectric layer in a pattern of the second trenches with an etching process; and
forming fifth trenches in the interlevel dielectric layer in a pattern of the third trenches with the etching process.

7. The method of claim 6, comprising forming the first metal lines in the fourth trenches and the second metal lines in the fifth trenches by depositing a metal with a deposition process.

8. The method of claim 7, comprising performing a chemical mechanical planarization process after the deposition process.

9. The method of claim 1, wherein the patterning layer is amorphous silicon.

10. The method of claim 1, wherein the hard mask layer includes a first hard mask sublayer on the interlevel dielectric layer, a second hard mask sublayer on the first hard mask sublayer, and a third hard mask sublayer on the second hard mask sublayer.

11. The method of claim 10, wherein the first and third hard mask sublayers are tetraethyl orthosilicate.

12. A method, comprising:
forming a plurality of first trenches in a patterning layer above an interlevel dielectric layer with a first photolithography and etching process;
forming a plurality of spacers each lining sidewalls of a respective first trench and isolated from each other;
forming a plurality of second trenches in a hard mask layer below the patterning layer with a second photolithography process; and
forming a plurality of third trenches in the hard mask layer laterally alternating with second trenches, the second and third trenches being laterally self-aligned with the spacers.

13. The method of claim 12, comprising:
forming fourth trenches in the interlevel dielectric layer in a pattern of the second trenches with a first etching process;
forming fifth trenches in the interlevel dielectric layer in a pattern of the third trenches with the first etching process; and
forming first metal lines in the fourth trenches; and
forming second metal lines in the fifth trenches by depositing the metal with the deposition process.

14. The method of claim 13, wherein the hard mask layer includes a first hard mask sublayer and a second hard mask sublayer on the first hard mask sublayer.

15. The method of claim 14, wherein:
forming the second trenches includes etching, with a second etching process before the first etching process, the second hard mask sublayer without etching the first hard mask sublayer; and
forming the third trenches includes etching, with a third etching process between the second etching process and the first etching process, the second hard mask sublayer without etching the first hard mask sublayer.

16. The method of claim 15, wherein forming the fourth and fifth trenches includes extending the second and third trenches through the first hard mask sublayer with a fourth etching process.

17. The method of claim 16, wherein the first hard mask layer includes carbon doped with tungsten, wherein the second hard mask layer includes tetraethyl orthosilicate.

18. An integrated circuit, comprising:
a plurality of transistors;
an interlevel dielectric layer above the transistors;
a plurality of first metal lines in the interlevel dielectric layer extending in a first lateral direction; and
a plurality of second metal lines in the interlevel dielectric layer extending in the first lateral direction and alternating with the first metal lines in a second lateral direction transverse to the first lateral direction, wherein the first metal lines have multiple different end-to-end dimensions, wherein the second metal lines have multiple different end-to-end dimensions.

19. The integrated circuit of claim 18, wherein the first and second metal lines are part of an SRAM cell.

20. The integrated circuit of claim 19, wherein the first and second metal lines are separated by a uniform separation distance in the second lateral direction.
